(19) United States
(12) Patent Application Publication
(10) Pub. No.: US 2024/0371630 A1
(43) Pub. Date: Nov. 7, 2024

(54) SEMICONDUCTOR DEVICE STRUCTURE AND MANUFACTURING METHOD THEREOF

(71) Applicant: Taiwan Semiconductor Manufacturing Company, Ltd., Hsinchu (TW)

(72) Inventors: I-Hsuan Lo, Hsinchu (TW); Wei-Ting Yeh, Hsinchu City (TW)

(73) Assignee: Taiwan Semiconductor Manufacturing Company, Ltd., Hsinchu (TW)

(21) Appl. No.: 18/311,890

(22) Filed: May 3, 2023

(51) Int. Cl. H01L 21/02; H01L 21/762; H01L 27/088; H01L 29/66

(52) U.S. Cl. CPC H01L 21/02271; H01L 21/0217; H01L 21/02219; H01L 21/0234; H01L 21/02348; H01L 21/76224; H01L 27/088; H01L 29/66439; H01L 29/66742

(57) ABSTRACT

A method for forming a semiconductor device structure is provided. The method includes forming a transistor layer over a substrate and forming a trench in the transistor layer. A depth to width ratio of the trench is greater than or equal to 3. The method further includes filling the trench with a gap-fill material using a flowable chemical vapor deposition process, wherein a precursor and a reactant are used in the flowable chemical vapor deposition process, and a ratio of the precursor to the reactant is about 1.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 15 are schematic perspective views at various stages in the formation of a semiconductor device structure in accordance with some embodiments of the disclosure.

FIG. 16 shows schematic cross-sectional views of various steps in a bottom-up deposition process during the formation of a semiconductor device structure in accordance with some embodiments of the disclosure.

FIG. 17 illustrates a possible reaction mechanism for the bottom-up deposition process as shown in FIG. 16, in accordance with some embodiments of the disclosure.

FIG. 18 is a schematic cross-sectional view of a portion of a semiconductor device structure after a bottom-up deposition process in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description. Source/drain structure(s) may refer to a source or a drain, individually or collectively dependent upon the context.

Although some embodiments described in this disclosure are described in the context of nanosheet channel FETs, implementations of some aspects of the present disclosure may be used in other processes and/or in other devices, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

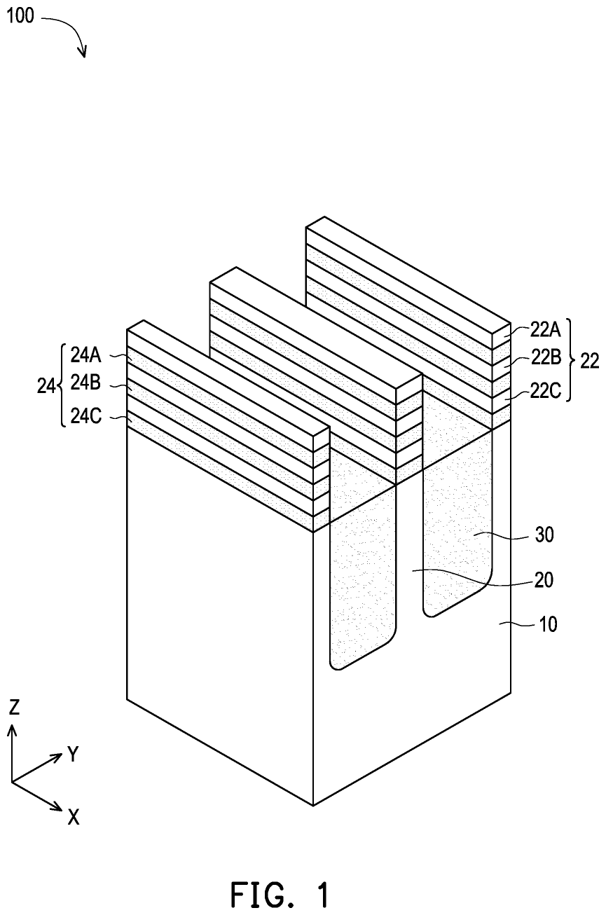

The various aspects of the present disclosure will now be described in more detail with reference to the figures. FIG. 1 through FIG. 15 are schematic perspective views at various stages in the formation of a semiconductor device structure 100 in accordance with some embodiments of the disclosure. It is understood that additional operations can be provided before, during, and after processes shown by FIG. 1 through FIG. 15, and some of the operations described below can be replaced or eliminated, for additional embodiments of the method. The order of the operations/processes may be interchangeable.

Referring to FIG. 1, a substrate 10 is provided. The substrate 10 may be a semiconductor substrate, such as a bulk semiconductor, or the like, which may be doped (e.g., with a p-type or an n-type dopant) or undoped. In some embodiments, the semiconductor material of the substrate 10 includes silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

A multi-layer stack (not shown) including alternating layers of first semiconductor layers and second semiconductor layers may be formed over the substrate 10 and then patterned to form a plurality of nanostructures 22, 24. As seen from FIG. 1, the semiconductor device structure 100 may include a front-side and a back-side opposite to the front-side, and the front-side of the semiconductor device structure 100 is referred to the side where the nanostructures 22, 24 are formed. In some embodiments, the back-side of the semiconductor device structure 100 may also be referred to as “substrate-side”.

In some embodiments, the first semiconductor layers are formed of a first semiconductor material, such as silicon, silicon carbide, or the like, and the second semiconductor layers are formed of a second semiconductor material different from the first semiconductor material, such as silicon germanium, or the like. In some further embodiments, the semiconductor materials of the first semiconductor layers and the second semiconductor layers are selected to have high etch selectivity relative to each other so that either the first or the second semiconductor layers can be removed during subsequent process without significantly removing the other. Each layer of the multi-layer stack may be epitaxially grown using a deposition process, such as a chemical vapor deposition (CVD), an atomic layer deposition (ALD), a vapor phase epitaxy (VPE), a molecular beam epitaxy (MBE), or the like.

Next, the multi-layer stack and the substrate 10 are patterned by one or more photolithography processes (e.g., double-patterning or multi-patterning processes) and a subsequent anisotropic etching process to form the fins 20 within the substrate 10 and the nanostructures 22, 24 over the substrate 10. The etching process may include a reactive ion etch (RIE), a neutral beam etch (NBE), the like, or a combination thereof. For example, first nanostructures 22A-22C (also referred to as “channels” below) are formed from the first semiconductor layers, and second nanostructures 24A-24C are formed from the second semiconductor layers. In some embodiments, the nanostructures 22, 24 are formed to extend along a first direction (e.g., X-direction) and to be arranged in parallel to one another in a second direction (e.g., Y-direction) perpendicular to the first direction. In some further embodiments, nanostructures 22, 24 are patterned to have rectangular cross-sectional shapes having substantially vertical sidewalls. However, it is understood that the nanostructures 22, 24 may include tapered sidewalls.

Isolation regions 30, which may be shallow trench isolation (STI) regions, are formed between adjacent fins 20. In some embodiments, the isolation regions 30 are formed by depositing an insulation material, such as oxide and/or nitride, over the substrate 10, the fins 20, and the nanostructures 22, 24. The deposition of the insulation material may include using a high-density plasma CVD (HDP-CVD) process, a flowable CVD (FCVD) process, the like, or a combination thereof. The insulation material is then planarized and recessed to form the isolation regions 30. In some embodiments, the planarization is performed using a chemical mechanical polish (CMP) process and/or an etch back process, and the recessing of the insulation material is performed using an acceptable etching process, such as an oxide removal process using diluted hydrofluoric acid (dHF). After the recessing, the nanostructures 22, 24 and upper portions of the fins 20 may protrude from adjacent isolation regions 30 as shown in FIG. 1. The isolation regions 30 may include top surfaces that are flat as illustrated. Alternatively, top surfaces of the isolation regions 30 may be convex, concave, or a combination thereof.

In some further embodiments, appropriate wells (not shown) may be formed in the fins 20, the nanostructures 22, 24, and/or the isolation regions 30. For example, an n-type impurity implantation is performed in p-type regions of the substrate 10, and a p-type impurity implantation is performed in n-type regions of the substrate 10. An annealing process may be performed after the implantations to repair implant damage and to activate the p-type and/or n-type impurities.

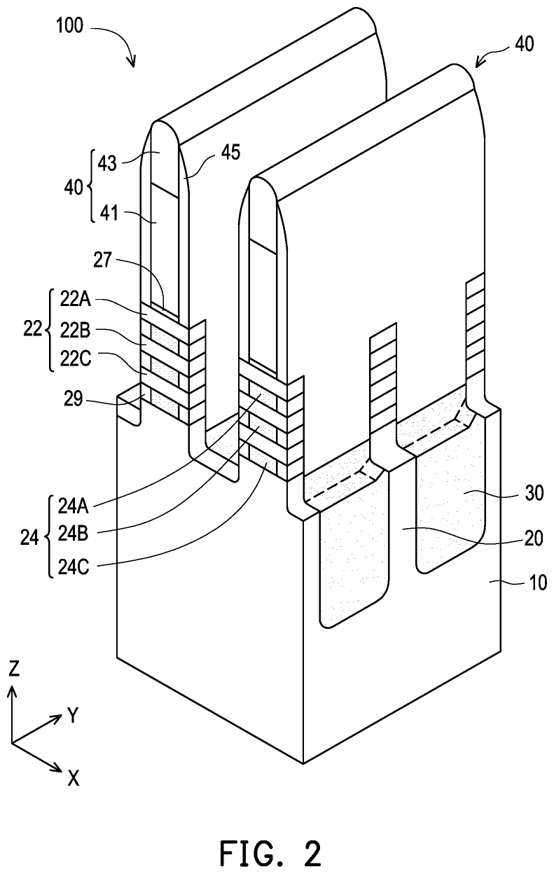

Referring to FIG. 2, a dielectric layer 27 is formed over the nanostructures 22, 24 and the isolation regions 30, and a plurality of dummy gate structures 40 are formed on the dielectric layer 27 over the nanostructures 22, 24. Each dummy gate structure 40 may include a dummy gate layer 41 and a mask layer 43 over the dummy gate layer 41. For example, the dielectric layer 27 is formed using a suitable deposition technique (such as a CVD process, a sub-atmospheric CVD (SACVD) process, an ALD process) to conformally cover exposed surfaces of the nanostructures 22, 24 and the isolation regions 30. In some embodiments, the dielectric layer 27 includes silicon oxide, silicon nitride, high-K dielectric material and/or other suitable material.

Thereafter, a dummy gate material layer is deposited on the dielectric layer 27 over the nanostructures 22, 24 and the isolation regions 30, in accordance with some embodiments. The dummy gate material layer may include conductive, semi-conductive, or non-conductive material. For example, the dummy gate material layer includes amorphous silicon, polycrystalline-silicon (polysilicon), poly-crystalline silicon-germanium (poly-SiGe), metallic nitrides, metallic silicides, metallic oxides, or metals. A mask material layer may be formed over the dummy gate material layer, and may include silicon nitride, silicon oxynitride, or the like. In some embodiments, the dummy gate material layer and the mask material layer are formed by physical vapor deposition (PVD), CVD, sputter deposition, or other suitable techniques.

The dummy gate material layer and the mask material layer are then patterned to form a plurality of discrete (i.e., separate) dummy gate structures 40 cach including a dummy gate layer 41 and a mask layer 43, in accordance with some embodiments. In some embodiments, the dummy gate structures 40 are formed to extend along the second direction (e.g., Y-direction) and to be arranged in parallel to one another in the first direction (e.g., X-direction). Next, spacers 45 may be formed on sidewalls of each dummy gate structure 40 (i.e., sidewalls of the dummy gate layer 41 and the mask layer 43). The spacers 45 are, for example, made of an insulation material, such as silicon nitride, silicon oxide, silicon carbo-nitride, silicon oxynitride, silicon oxy carbo-nitride, or the like. The spacers 45 may be formed by depositing a spacer material layer (not shown) over the dummy gate structures 40. Portions of the spacer material layer are removed using an anisotropic etching process, leaving the spacers 45 on sidewalls of cach dummy gate structure 40, in accordance with some embodiments.

Still referring to FIG. 2, an etching process is performed to etch the portions of protruding fins 20 and/or nanostructures 22, 24 that are not covered by dummy gate structures 40 and the spacers 45, and a selective etching process is then performed to recess end portions of the nanostructures 24 to further form inner spacers 29 in the recesses (not shown). In some embodiments, the etching process is anisotropic, such that the portions of fins 20 directly under the dummy gate structures 40 and the spacers 45 are protected from being etched. In addition, the etching process may also etch away an upper portion of the isolation regions 30. In some embodiments, a suitable dielectric material such as silicon nitride (SiN), silicon oxycarbide (SiOC), silicon carbon nitride (SiCN), silicon oxycarbonitride (SiOCN) is deposited to fill the recesses after the selective etching process. For example, a suitable deposition technique such as PVD, CVD, ALD, or the like is used to deposit an inner spacer layer, and then an anisotropic etching process is performed to remove portions of the inner spacer layer outside the recesses. The remaining portions of the inner spacer layer (e.g., portions disposed inside the recesses) form the inner spacers 29, for example. As shown in FIG. 2, outer sidewalls of the inner spacers 29 may be substantially flush with outer sidewalls of the nanostructures 22 and outer sidewalls of the spacers 45.

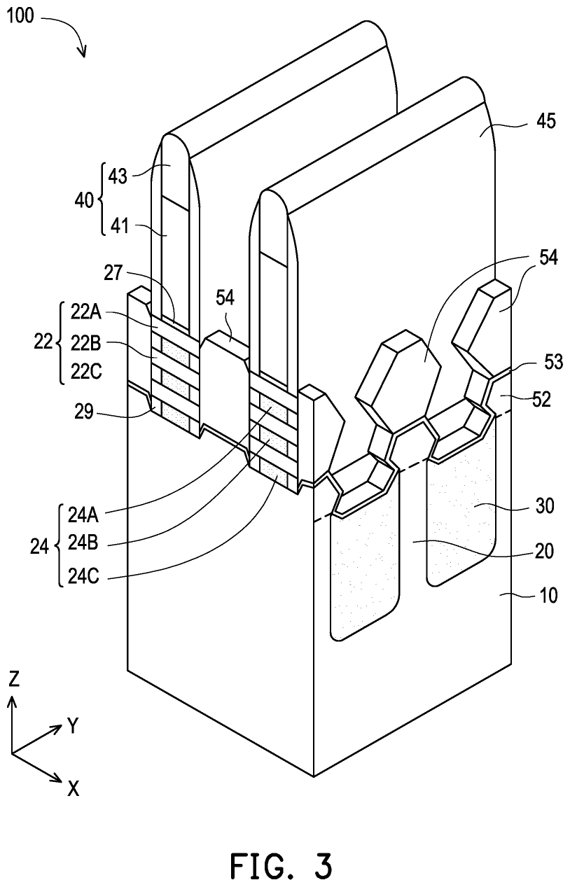

Referring to FIG. 3, in some embodiments, elevated epitaxial structures 52 and source/drain structures 54 over the elevated epitaxial structures 52 are formed. For example, a bottom-up epitaxial growth process is performed on exposed surfaces of the fins 20 to form the elevated epitaxial structures 52. Generally, the elevated epitaxial structures 52 may include a diamond shape profile or a bottom-up growth profile, due to the differences in growth rates in different directions. In some embodiments, the elevated epitaxial structures 52 are formed in a hexagonal shape from cross-sectional view as illustrated in FIG. 3. However, the bottom-up growth profiles of the elevated epitaxial structures 52 may include any suitable cross-sectional shapes, such as a circular shape, a square shape, or a diamond shape. In some embodiments, the elevated epitaxial structures 52 is formed of a material similar to, or the same as, those of the fins 20 (e.g., material of the substrate 10), such as silicon.

In some embodiments, a dielectric layer 53 is formed to conformally cover the exposed surfaces of the elevated epitaxial structures 52 and the recessed isolation regions 30. The dielectric layer 53 may be formed of oxides, such as silicon oxide (SiO), aluminum oxide (AlO), zirconium oxide (ZrO), hafnium oxide (HfO), titanium oxide (TiO), zirconium aluminum oxide (ZrAlO), zinc oxide (ZnO); nitrides, such as silicon nitride (SiN); oxynitrides, such as aluminum oxynitride (AlON); SiCN, SiOCN; or the like. The dielectric layer 53 may be formed by CVD, plasma-enhanced CVD (PECVD), ALD, or any suitable deposition technique.

In some embodiments, thereafter, source/drain structures 54 are formed on the dielectric layer 53 over the elevated epitaxial structures 52. In some embodiments, the source/drain structures 54 are formed by an epitaxial growth process and include an angled, curved or irregular profile. For example, the source/drain structures 54 are illustrated with a hexagonal-shaped profile in FIG. 3. The source/drain structures 54 may exert stress in the respective channels 22A-22C, thereby improving the performance of the transistor(s). Each dummy gate structure 40 is sandwiched between a corresponding pair of the source/drain structures 54. In addition, the spacers 45 separate the source/drain structures 54 from the dummy gate layer 41 with an appropriate lateral distance to prevent electrical bridging between the source/drain structures 54 and subsequently formed metal gate structures, for example.

In some embodiments, the source/drain structures 54 may include any acceptable material, for example, appropriate for n-type or p-type devices. For n-type devices, the source/drain structures 54 may include materials exerting a tensile strain in the channel regions, such as silicon, SiC, SiCP, SiP, or the like. For P-type devices, the source/drain structures 54 include materials exerting a compressive strain in the channel regions, such as SiGe, SiGeB, Ge, GeSn, or the like, according to some embodiments. Alternatively, adjacent source/drain structures 54 may merge to form a singular source/drain region alongside two or more adjacent nanostructures 22, 24. Furthermore, in some embodiments, the source/drain structures 54 are implanted with dopants and then undergo an annealing process. In some embodiments, the source/drain structures 54 are in-situ doped during growth.

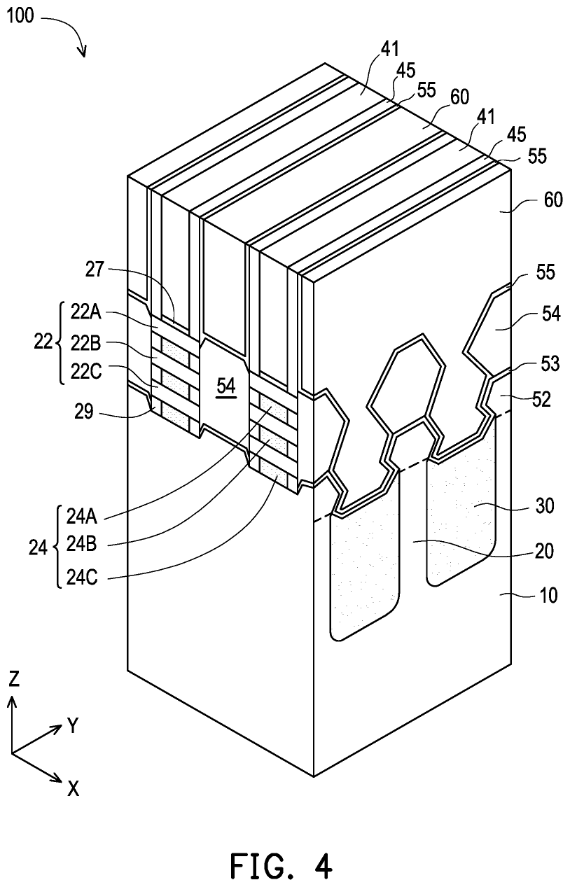

Turning to FIG. 4, in some embodiments, a contact etch stop layer (CESL) 55 and an interlayer dielectric (ILD) layer 60 are sequentially formed to cover the dummy gate structures 40 and the source/drain structures 54. For example, the CESL 55 is conformally formed on the exposed surfaces of the semiconductor device structure 100 shown in FIG. 3. In some embodiments, the CESL 55 includes an oxygen-containing material such as silicon oxide and silicon carbon oxide, or a nitrogen-containing material such as silicon nitride, silicon carbon nitride, silicon oxynitride and carbon nitride, or a combination thereof. In some embodiments, the CESL 55 is formed by CVD, PECVD. ALD, or any suitable deposition technique.

Referring to FIG. 4, in some embodiments, the ILD layer 60 is then formed on the CESL 55, such that the spaces between the dummy gate structures 40 are filled by the ILD layer 60. In some embodiments, the materials for the ILD layer 60 include compounds comprising Si, O, C, and/or H, such as silicon oxide, TEOS oxide, SiCOH and SiOC. Organic materials, such as polymers, may also be used for the ILD layer 60. The ILD layer 60 may be deposited by PECVD, FCVD, or other suitable deposition technique. In some embodiments, after the formation of the ILD layer 60, the semiconductor device structure 100 is subject to a thermal process to anneal the ILD layer 60. Further, a planarization process, such as a CMP, may be performed from the front-side of the semiconductor device structure 100 until the dummy gate layers 41 are exposed. For example, the mask layer 43 is entirely removed during the planarization process. In some embodiments, top surfaces of the dummy gate layers 41, the spacers 45, the ILD layer 60 and the CESL 55 are substantially coplanar with one another after the planarization process.

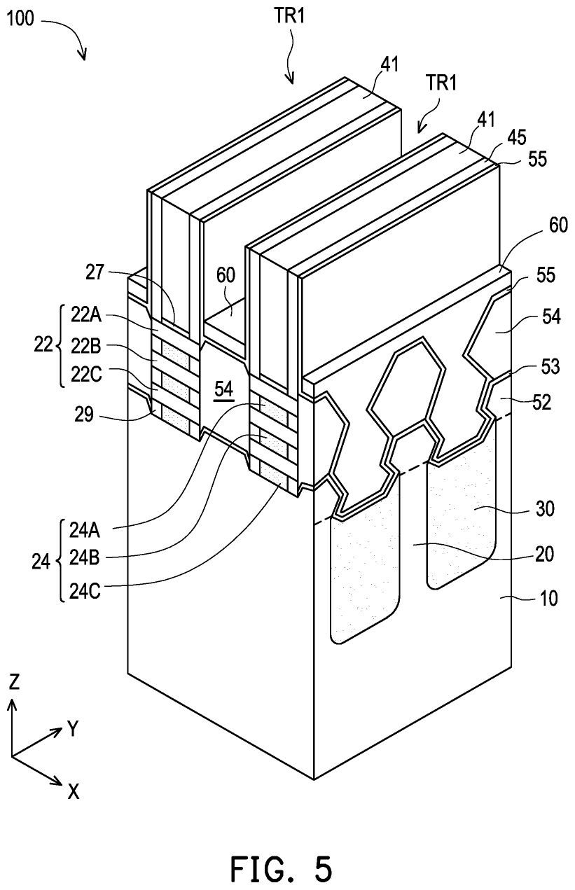

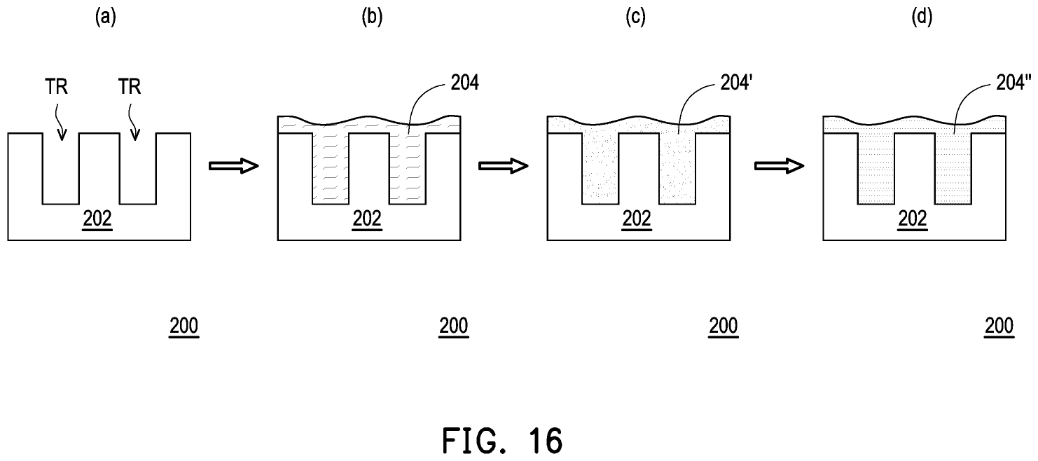

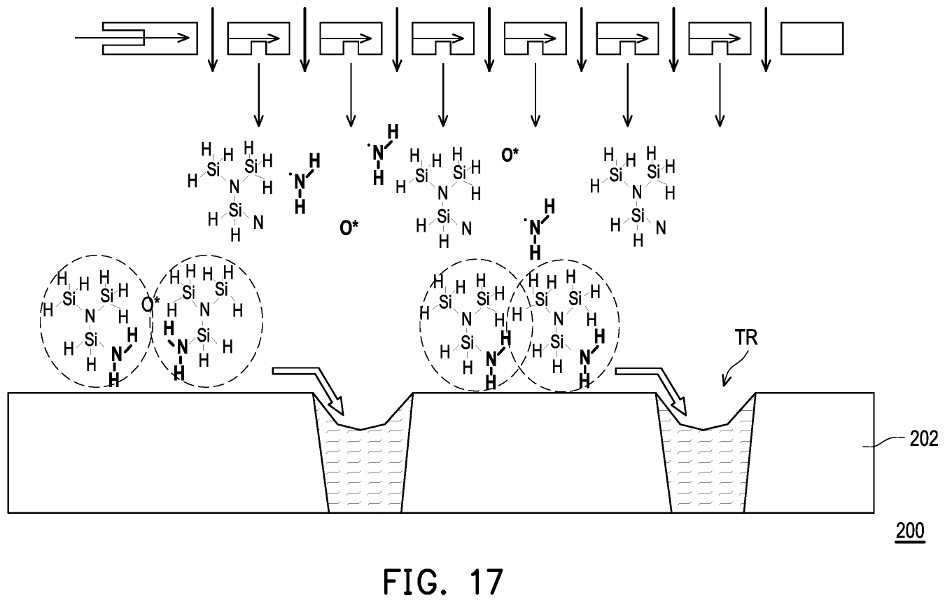

Referring to FIG. 5, in some embodiments, the ILD layer 60 is recessed, thereby forming trenches TR1. For example, an anisotropic etching process such as an etch back process is performed to partially remove the ILD layer 60. In one embodiment, the ILD layer 60 is etched back with a depth less than 100 nm. Thereafter, a gap-fill material is formed through a novel bottom-up gap filling deposition process, and the gap-fill material formed through such deposition process covers the ILD layer 60 and fills up the trenches TR1. In some embodiments, the bottom-up gap filling deposition process is performed until the exposed top surfaces of the dummy gate layers 41, the spacers 45, the CESL 55, and the ILD layer 60 are fully covered. In certain embodiments of the present disclosure, the gap-fill material is or includes silicon nitride. The novel bottom-up gap filling deposition process for forming the gap-fill material (e.g., silicon nitride) and filling the trenches TR1 with the gap-fill material will be described later with reference to FIG. 16 through FIG. 17. By using the above-mentioned bottom-up deposition process, the so-formed silicon nitride layer full fills up the trenches TR1, and the silicon nitride layer filled in the trenches TR1 is void-free and seam-free. It is important to form the void-free and seam-free gap-fill material filled into the trenches because no slit or gap may be formed in the gap-fill material after planarized or polished and better insulation and/or isolation is provided in the subsequent processes.

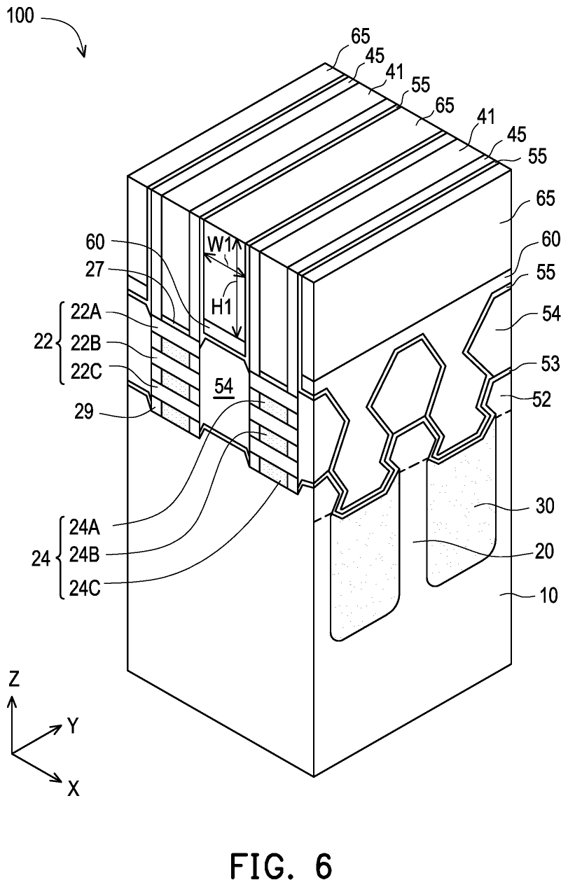

After the deposition of the gap-fill material, a planarization process is performed to expose the dummy gate layers 41, the spacers 45, and the CESL 55. In one embodiment, the planarization process includes CMP or grinding process. After the CMP process, the remained gap-fill material in the trenches TR1 and over the ILD layer 60 form hard mask layers 65. In some embodiments, the hard mask layer 65 is used to protect the underlying ILD 60 from damage during a subsequent gate replacement process. As shown in FIG. 6, top surfaces of the dummy gate layers 41, the spacers 45, the CESL 55, and the hard mask layer 65 are coplanar with one another after the planarization process. In some embodiments, the hard mask layer 65 has a height H1 substantially equal to or less than the etched-back vertical dimension of the ILD layer 60. In addition, the hard mask layer 65 has a width W1 substantially equal to a lateral distance between the CESLs 55 on adjacent dummy gate structures. In some other embodiments, a height to width ratio (H1/W1) of the hard mask layer 65 is no less than 3. In other words, the previously formed trenches TR1 are, for example, high aspect ratio openings.

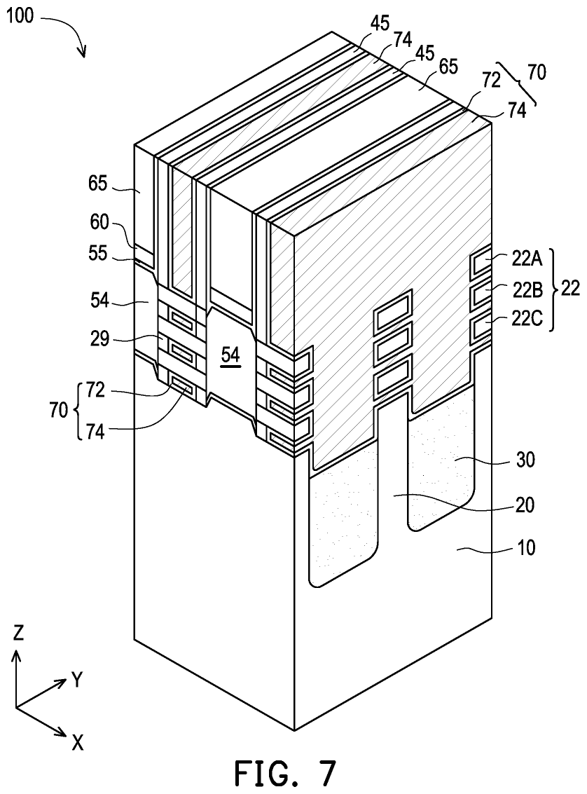

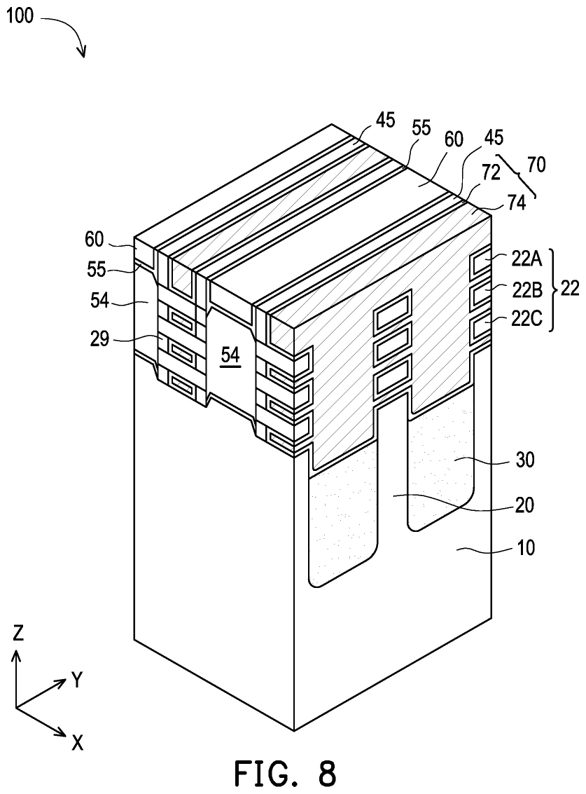

Referring to FIG. 7 and FIG. 8, a gate replacement process is performed to replace the dummy gate layers 41 with a gate electrode layer 70. For the clarity of discussion, FIG. 7 thereafter shows perspective view of the semiconductor device structure 100 in a different YZ cross-section. For example, the nanostructures 22, 24 are shown in YZ cross-section in FIGS. 7-15. The gate replacement process begins with removing the dummy gate layers 41. In some embodiments, the dummy gate layers 41 are removed using one or more suitable dry etching processes and/or wet etching processes. For example, in cases where the dummy gate layers 41 are polysilicon and the ILD layer 60 is silicon oxide, a wet etchant, such as a tetramethylammonium hydroxide (TMAH) solution is used to selectively remove the dummy gate layers 41 without removing the dielectric materials of the hard mask layers 65, the ILD layer 60, the CESL 55, the spacers 45, and the dielectric layer 27. In some embodiments, the source/drain structures 54 are protected by the hard mask layers 65, the ILD layer 60 and the CESL 55 during the removal of the dummy gate layers 41.

Next, in some embodiments, the dielectric layer 27 conformally formed on the nanostructures 22, 24 is removed using plasma dry etching and/or wet etching, for example. In some embodiments, the removal of the dielectric layer 27 causes damages to the insulation material of the isolation regions 30, thereby partially recessing the isolation regions 30. The removal of the dummy gate layers 41 and the dielectric layer 27 together form trenches (not shown) exposing the nanostructures 22, 24, the isolation regions 30 and the outer sidewalls of the spacers 45.

In some embodiments, the second nanostructures 24A-24C are then removed from the trenches (not shown), while the first nanostructures 22A-22C are remained. In some embodiments, the removal of the second nanostructures 24A-24C results in multiple gaps formed between the first nanostructures 22A-22C connecting to the source/drain structures 54. Accordingly, each of the first nanostructures 22A-22C has surfaces (e.g., top surface and bottom surface) exposed by the gaps, and the exposed surfaces are opposite to each other and are perpendicular to the longitudinal direction (e.g., the Z-direction). In some embodiments, the exposed surfaces will be surrounded by a subsequently formed gate layer, and each of the first nanostructures 22A-22C forms a nanosheet channel of the nanoshect transistor. In some embodiments, the first nanostructures 22 may be referred to as nanostructure stacks cach including a plurality of nanostructures (e.g., first nanostructures 22A-22C) stacked over one another.

In some embodiments, the second nanostructures 24A-24C are removed using any suitable selective removal process, such as a selective wet etching process and a selective dry etching process. After the formation of the nanosheet channels (i.e., the first nanostructures 22A-22C), a gate dielectric layer 72 is conformally formed on surfaces exposed by the trenches and gaps, in accordance with some embodiments. For example, the gate dielectric layer 72 is formed to wrap around each of the first nanostructures 22A-22C and to cover exposed surfaces of the isolation regions 30 and the fins 20 and the sidewalls of the spacers 45. In some embodiments, the gate dielectric layer 72 includes one or more layers of a dielectric material, such as silicon oxide, silicon nitride, high-K dielectric material, other suitable dielectric material, and/or a combination thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or a combination thereof. In one embodiment, the gate dielectric layer 72 is formed using a conformal deposition process, such as ALD to ensure that a gate dielectric layer of uniform thickness is formed around each of the first nanostructures 22A-22C.

In some embodiments, a gate layer 74 is formed on the gate dielectric layer 72 to surround a portion of each of the first nanostructures 22A-22C, and further fill the trenches and the gaps. For example, the gate layer 74 is deposited until top surfaces of the spacers 45, the CESL 55. the ILD layer 60, and the hard mask layers 65 are covered. In some embodiments, the gate layer 74 includes one or more layers of metallic materials, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and/or any combinations thereof. In some embodiments, the gate layer 74 includes a conductive material, such as polysilicon. For example, the gate layer 74 may be formed by CVD, ALD, electro-plating, or other suitable deposition technique.

In some embodiments, as the gap-fill material of the hard mask 65 is void-free and seam-free, no metal penetration or diffusion occurs in the gap-fill material during the formation of the metallic gate layer of the gate replacement process. Hence, the gap-fill material of the hard mask 65 provides better masking effect or better protection for the underlying layer(s), thereby improving the device performance.

In some embodiments, a planarization process is performed on the semiconductor device structure 100 shown in FIG. 7 until the ILD layer 60 is exposed, and the planarized structure is shown in FIG. 8. For example, the planarization process is performed using CMP or grinding process, and the hard mask layer 65 may be completely removed after the planarization process. In some embodiments, the remaining gate dielectric layer 72 and gate layer 74 are collectively referred to as a gate electrode layer 70. In some embodiments, subsequent to the planarization process, top surfaces of the gate electrode layers 70, the ILD layer 60, the CESL 55, and the spacers 45 are substantially coplanar with one another. As shown in FIG. 8, the gate electrode layer 70 wraps around the nanostructures 22 and extends between the adjacent nanostructure stacks (e.g., each nanostructure stack including the nanostructures 22A-22C stacked over each other). In addition, the first nanostructures 22, the source/drain structures 54, and the gate electrode layer 70 (including the gate dielectric layer 72 and the gate layer 74) may be collectively referred to as transistor structures.

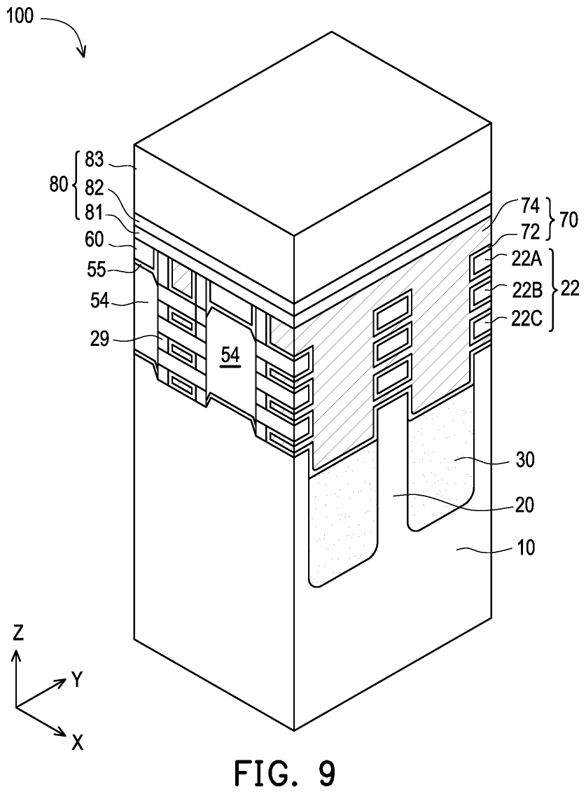

Referring to FIG. 9, a hard mask stack 80 including a first hard mask layer 81, a second hard mask layer 82, and a third hard mask layer 83 is sequentially formed over the semiconductor device structure 100 shown in FIG. 8. For example, the hard mask stack 80 directly covers the gate electrode layer 70, the ILD layer 60, the CESL 55, and the spacer 45. In some embodiments, the first and third hard mask layers 81, 83 include similar or substantially the same material, and the second hard mask layer 82 includes a material different from that of the first and third hard mask layers 81, 83. In one embodiment, the first and third hard mask layers 81, 83 are formed of silicon nitride and the second hard mask layer 82 is formed of silicon such as amorphous silicon (α-Si). Each of the hard mask layers of the hard mask stack 80 is deposited using a process such as CVD, PECVD, or ALD. In some further embodiments, the hard mask layers 81, 82, and 83 are formed to have different thicknesses. For example, the third hard mask layer 83 is formed to be much thicker than the first and second mask layers 81, 82.

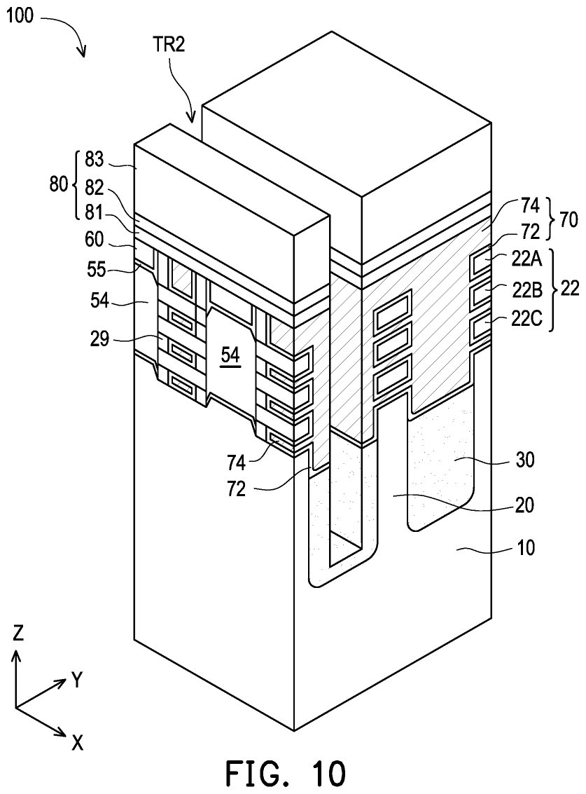

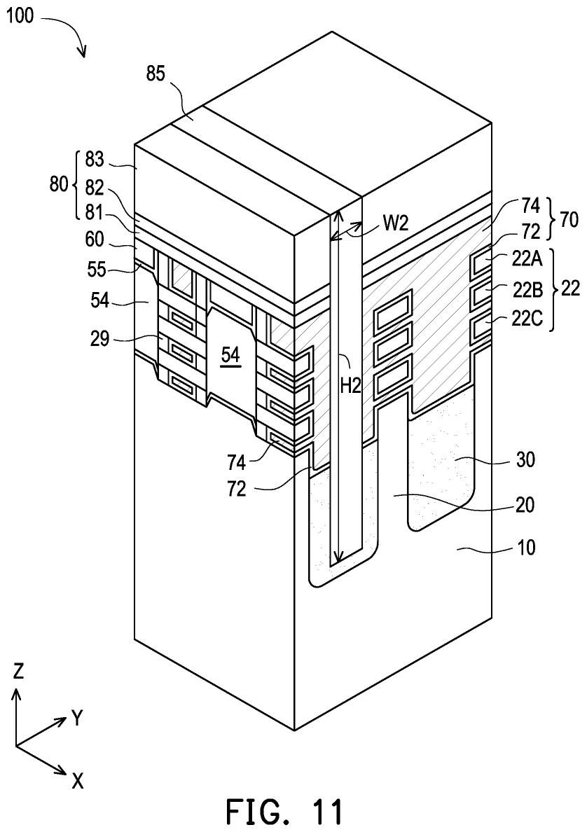

Referring to FIG. 10 and FIG. 11, a cut metal gate (CMG) process is performed. In some embodiments, the CMG process is used for forming isolation structure to separate/divide a continuous gate electrode (i.e., the gate electrode layer 70) that spans over multiple nanostructure stacks into multiple segments. Such isolation structures may be referred to as gate cut features or CMG features, and each segment of the cut metal gate may serve as a gate electrode of an individual transistor.

To form the gate cut feature, a gate cut trench (or opening) TR2 separating the gate electrode layer 70 is first formed, as illustrated in FIG. 10. The formation of the gate cut trench TR2 may include performing a patterning process using one or more photolithography processes and a subsequent anisotropic etching process. After the patterning process, the gate cut trench TR2 extends from the hard mask stack 80 and all the way through a major portion of the isolation regions 30. As shown in FIG. 10, isolation regions 30 are exposed at the bottom of the gate cut trench TR2. The gate cut trench TR2 may penetrate into or through the isolation regions 30, depending on product design. In some embodiments, the gate cut trench TR2 has a longitudinal direction in XY plane extending along the first direction (i.e., the X-direction) of the previously formed nanostructures 22, 24. In some other embodiments, the gate cut trench TR2 is formed with substantially vertical sidewalls. Alternatively, the gate cut trench TR2 may include tapered sidewalls.

Thereafter, the gate cut trench TR2 is filled with a gap-fill material using a bottom-up gap filling deposition process followed by a planarization process. In some embodiments, the gap-fill material includes an insulation material such as silicon nitride. The bottom-up deposition process may be performed until a top surface of the hard mask layer 80 is covered with the gap-fill material (e.g., silicon nitride). The bottom-up gap filling deposition process for filling in the gate cut trench TR2 is similar to the gap filling deposition process of the trench TR1, which will be described later with reference to FIG. 16 through FIG. 17. By using a bottom-up deposition process according to the embodiments of the present disclosure, the gate cut trench TR2 is completely filled up by the formed gap-fill material, and the gap filled material is formed without voids or seams in the gate cut trench TR2.

In some embodiments, the subsequent planarization process includes CMP or grinding process. The remaining gap-fill material in the gate cut trench TR2 forms the gate cut feature 85. As shown in FIG. 11, top surfaces of the third hard mask layer 83 and the gate cut feature 85 are coplanar with each other after the planarization process. In some embodiments, the void-free or seam-free gate cut feature 85 can provide good isolation between gate electrodes of adjacent transistors. A height H2 of the gate cut feature 85 may be substantially equal to or less than that of the gate cut trench TR2, and a height to width ratio (H2/W2) of the gate cut feature 85 may be no less than 3. That is, the previously formed gate cut trench TR2 is, for example, an opening with a high aspect ratio. It should be noted that, the number and arrangement of the gate cut feature 85 shown in FIG. 10 is merely an example. Other arrangements and layouts are also possible and more than one gate cut feature 85 may also be formed.

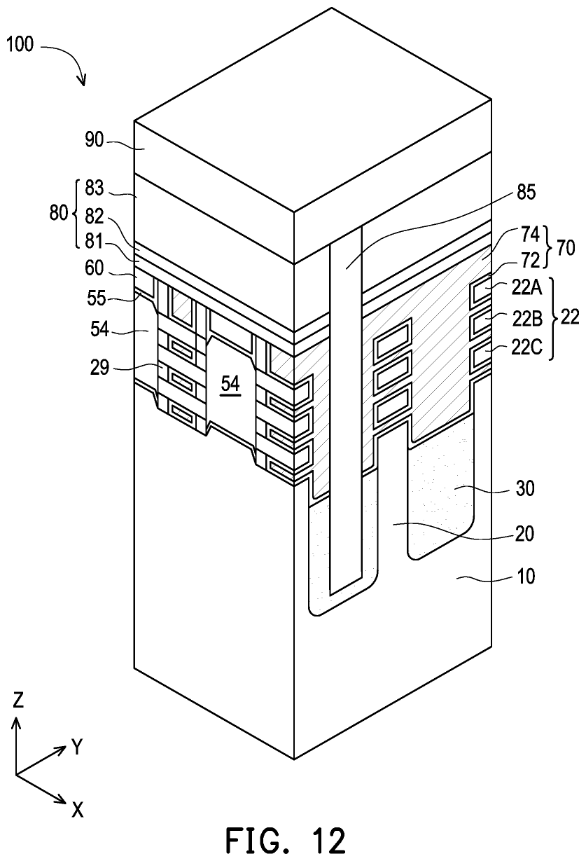

Turning to FIG. 12, a fourth hard mask layer 90 is formed over the hard mask stack 80 and the gate cut feature 85. In some embodiments, the fourth hard mask layer 90 is formed for a later patterning process that defines the active device region by forming isolation structures in the semiconductor device structure 100. In some embodiments, the fourth hard mask layer 90 is formed of a material similar to that of the third hard mask layer 83. In one embodiment, the fourth hard mask layer 90 includes silicon nitride. In some embodiments, the fourth hard mask layer may be formed using a suitable deposition process such as CVD, PECVD, or ALD.

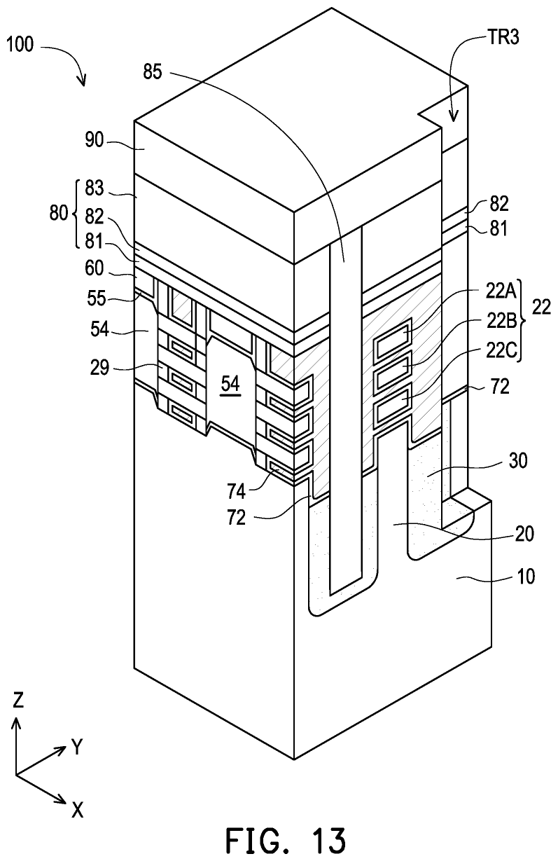

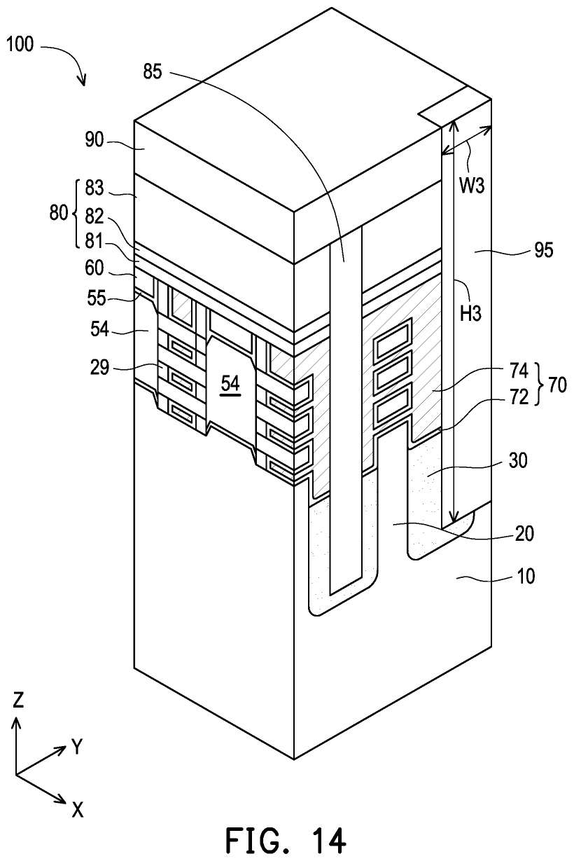

Referring to FIG. 13 and FIG. 14, a patterning process is performed and isolation structures 95 are formed. Generally, the isolation structure 95 is a dummy structure or a non-functional structure. In some embodiments, the isolation structure 95 is obtained by first forming a trench TR3, and then filling the trench TR3 with an insulation material. In some embodiments, the formation of the trench TR3 includes performing a patterning process using one or more photolithography processes and a subsequent anisotropic etching process. After the patterning process, the trench TR3 extends from the fourth hard mask layer 90, through the hard mask stack 80, and extends downward into the isolation region(s) 30. As shown in FIG. 13, a portion of the isolation region 30 is removed and the remained isolation region 30 is exposed by the trench TR3. The trench TR3 may penetrate into or through the isolation regions 30, depending on product design. In some embodiments, the trench TR3 has a longitudinal direction in XY plane extending along the second direction (i.e., the Y-direction) of the previously formed dummy gate structures 40. In some other embodiments, the trench TR3 is formed with substantially vertical sidewalls. Alternatively, the trench TR3 may include tapered sidewalls.

In some embodiments, thereafter, the trench TR3 is filled up with a gap-fill material (i.e. an insulating material) using a bottom-up deposition process followed by a planarization process. In some embodiments, the gap-fill material is or includes silicon nitride. In some embodiments, the bottom-up deposition process is performed until a top surface of the fourth hard mask layer 90 is covered with the gap-fill material (e.g., silicon nitride). The bottom-up gap filling deposition process for filling in the trench TR3 is similar to those processes for filling the trench TR1 and the gate cut trench TR2 which will be described later with reference to FIG. 16 through FIG. 17. By using a bottom-up deposition process according to the embodiments of the present disclosure, the trench TR3 is fully filled up with the gap-fill material, and the gap-fill material is formed without voids or seams in the trench TR3.

In some embodiments, the subsequent planarization process includes CMP or grinding process. The remained gap-fill material in the trench TR3 forms the isolation structure 95, which serves as a non-functional isolation structure. As shown in FIG. 14. top surfaces of the fourth hard mask layer 90 and the isolation structure 95 are coplanar with each other after the planarization process. In some embodiments, the void-free or seam-free isolation structure 95 can provide good isolation between adjacent cells. A height H3 of the isolation structure 95 may be substantially equal to or less than that of the trench TR3, and a height to width ratio (H3/W3) of the isolation structure 95 may be no less than 3. That is, the previously formed trench TR3 is, for example, an opening with a high aspect ratio. It should be noted that, the number and arrangement of the isolation structure 95 shown in FIG. 14 is merely an example. Other arrangements and layouts are also possible and more than one isolation structure 95 may also be formed.

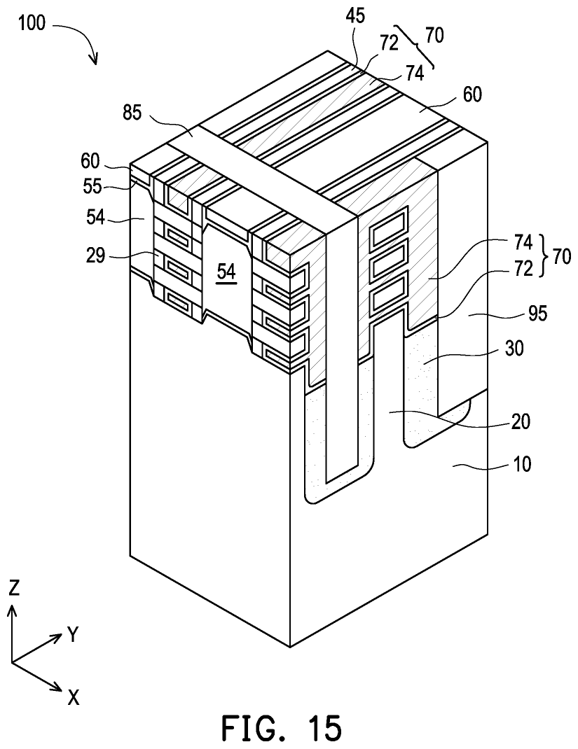

Referring to FIG. 15, a planarization process such as CMP or grinding process is performed on the front-side of the semiconductor device structure 100 shown in FIG. 14 until the gate electrode layer 70 is exposed. After the planarization process, top surfaces of the remaining portions of the isolation structure 95, the gate cut feature 85, the gate electrode layer 70, the ILD layer 60, the CESL 55, and the spacers 42 are substantially coplanar to one another. In other words, with the bottoms of the trenches TR2 and TR3 at the same horizontal level, the isolation structure 95 and the gate cut feature 85 may have substantially same height.

Up to here, a transistor layer of a semiconductor device structure 100 is fabricated. The transistor layer here generally refers to the layer formed over the substrate 10 as illustrated in FIG. 15. For example, the transistor layer includes the fins 20 and the nanostructures 22 functioned as channels, the isolation regions 30, the source/drain structures 54, the gate electrode layer 70 and dummy structures (i.e., non-functional structures) such as the gate cut feature 85 and the isolation structure 95.

Furthermore, after the transistor layer is formed, conductive features such as source/drain contact structures, gate contact structures, and other contacts may be formed over the transistor layer to enable electrical connection to the transistor (e.g., within the transistor layer) of the semiconductor device structure 100.

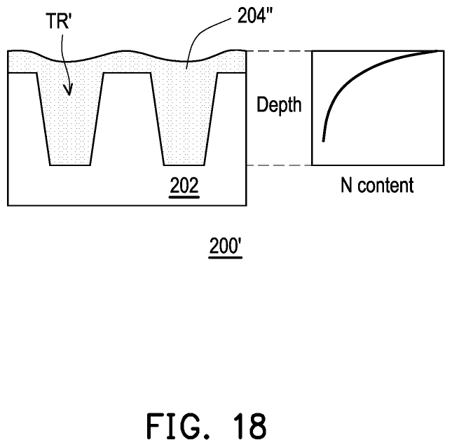

FIG. 16 shows schematic cross-sectional views of various steps in a bottom-up deposition process during the formation of a transistor layer of a semiconductor device structure 100 in accordance with some embodiments of the disclosure. FIG. 17 illustrates a possible reaction mechanism for the bottom-up deposition process, and FIG. 18 shows another schematic cross-sectional view of a portion of the semiconductor device structure 100 after the bottom-up deposition process. The bottom-up deposition process will be further described below in conjunction with FIGS. 16-18.

Referring to FIG. 16, a simplified semiconductor device structure 200 is shown in each step (a)-(d) of the bottom-up deposition process. The simplified semiconductor device structure 200 is very similar to the semiconductor device structure 100, and a transistor layer 202 is shown as a simplification of the transistor layer of the semiconductor device structure 100. For example, the transistor layer 202 is fabricated over a substrate (not shown) using suitable processes including film deposition process, epitaxy process, thermal process, photolithography process, etching process, material filling process, and planarization process, among others.

For ease of understanding, the semiconductor device structure 200 in FIG. 16 only shows trenches TR in the transistor layer 202. In some embodiments, the trenches TR may represent the trenches TR1, TR2, TR3 as described respectively in FIG. 5, FIG. 10, and FIG. 13. In some embodiments, a depth of the trench TR ranges from about 15 nm to about 300 nm, and a width of the trench TR ranges from about 3 nm to about 150 nm. In other words, an aspect ratio (i.e., depth to width ratio) may be greater than or equal to 3. Although the trenches TR in FIG. 16 are shown with substantially vertical sidewalls; however, the trenches may be etched to have tapered sidewalls, such as the trenches TR′ shown in FIG. 18. A bottom-up gap filling deposition process is then performed to fill the high aspect ratio trenches TR (i.e., trenches TR1, TR2, TR3) with gap-fill material. In one embodiment, the gap-fill material filling the trenches TR is silicon nitride.

As shown in steps (b)-(d) of FIG. 16, the bottom-up gap filling deposition process includes at least three processing steps. For example, the bottom-up deposition process includes firstly depositing a nitride-based polymer 204 in the trenches TR (see step (b)) using flowable CVD, then performing an ultraviolet (UV) curing process to solidify the nitride-based polymer 204 into a cured silicon nitride film 204′ (see step (c)). and performing a plasma treatment to densify the cured silicon nitride film 204′ to form a treated silicon nitride film 204″ (see step (d)). In addition, owing to the bottom-up deposition mechanism of the flowable CVD, the deposited film (i.e., 204, 204′, 204″) may have a curved top surface without seams, as illustrated in FIGS. 16 and 18.

In step (b) and referring to FIG. 17 together, a shower head 300 of a CVD tool (not specifically shown) may be used to introduce vapor phase precursors and reactants into the process chamber (i.e., CVD chamber) to react and form a nitride-based polymer (e.g., SiNO:H) filling the trenches TR. For example, the precursors and reactants may be simultaneously introduced into the CVD chamber through different sets of holes, as illustrated in FIG. 17. In some embodiments, the precursors may be trisilylamine ((Si₃H)₃N, TSA) introduced into the chamber via a carrier gas of Helium (He), and the reactants may be ammonia (NH₃) and oxygen (O₂). In one embodiment, the ratio of the precursors (TSA) to the reactants (NH₃+O₂) may be controlled at about 1 to form short-chain nitride-based polymers with good flowability (or, fluidity) to completely fill up the spaces of the trenches through the bottom-up mechanism. In such embodiments, the as-formed nitride-based polymer exhibits a liquid-like nature. In some embodiments, the flowable CVD may be performed at a suitable temperature ranging from about 0° C. to about 200° C. and under a pressure ranging from about a few Torr to about 30 Torr.

By implementing such bottom-up mechanism of the flowable CVD to fill or refill the trenches TR with a gap-fill material (i.e., deposited nitride-based polymer 204), the formation of voids or vertical seams can be avoided in as-formed gap-fill material, thereby offering better isolation and improving device performance and yield. Compared to other deposition processes such as ALD and PEALD, the flowable CVD is usually performed at a lower temperature (for example, about 65° C.) with a lower thermal budget, which can effectively reduce the diffusion of the dopants within the transistor layer. In addition, the gap filling process using the flowable CVD also prevents plasma damages to the under-layer(s), when compared with other plasma assisted deposition processes such as plasma enhanced CVD (PECVD) or plasma-enhanced ALD (PEALD). In some embodiments, further modification of the deposited nitride-based polymer 204 may be necessary because the chemical bonding of the short-chain polymer only includes hydrogen bonding (e.g., through van der Waal forces).

In step (c), the deposited nitride-based polymer 204 is subjected to an UV curing using a UV light with wavelength of about 100 nm to about 400 nm. In some embodiments, the UV curing is performed at a temperature ranging from about 0° C. to about 200° C. and under a pressure ranging from about a few Torr to about 30 Torr. A diluted gas such as Ar, He, hydrogen (H₂), neon (Ne), krypton (Kr), and xenon (Xe) may be used during the UV curing. In one embodiment, a pure Ar environment is provided for the UV curing to minimize an out-gassing effect. The nitride-based polymer can be fully cured and the crosslinked by using UV light with high reactivity and penetration capability. In addition, the UV curing is often carried out at a low temperature such as 10° C. and thus the thermal budget can be reduced. According to some embodiments, the UV curing also contributes to reducing impurities in the nitride-based polymer 204. The cured silicon nitride film 204′ may exhibit a solid-like nature after the UV curing.

In step (d), a nitrogen plasma treatment is performed to further densify the cured silicon nitride film 204′ to become the treated silicon nitride film 204″. In some embodiments, the nitrogen plasma treatment injects nitrogen into the material, drives impurities out of the film, and increases nitrogen/silicon (N/Si) ratios of the cured silicon nitride film 204′, which significantly improves the film quality. In some embodiments, the nitrogen plasma treatment includes a single-step process or a multi-step process. For example, microwave (MW), Electron Cyclotron Resonance (ECR), Capacitively Coupled Plasma (CCP), and Inductively Coupled Plasma (ICP) can be used for the nitrogen plasma treatment. The nitrogen source may be nitrogen ion (N, N₂), nitrogen radical (N·, N₂·), NH ion (NH, NH₂, NH₃), and/or NH radical (NH·, NH₂·, NH₃·). In some embodiment, a diluted gas such as Ar, He, H₂, Ne, Kr, and Xe may be used during the nitrogen plasma treatment.

In some embodiments, the MW plasma treatment is performed with a process temperature of about 200°° C. to about 500° C. and a process pressure of about 1 milli-torr (mTorr) to about 5 mTorr. In some embodiments, the ECR plasma treatment is performed with a process temperature of about 0°° C. to about 200° C. and a process pressure of about 1 mTorr to about 5 mTorr. In some embodiments the ICP or CCP plasma treatment is applied with a process temperature of about 300° C. to about 700° C. and a process pressure of about 1 mTorr to about 22 mTorr.

Furthermore, compared with the untreated silicon nitride film, the treated silicon nitride film 204″ may exhibit higher film density and higher etching resistance. For example, the treated silicon nitride film 204″ may have a film density of about 2.4 g/cm³ to about 2.6 g/cm³, and a wet etching rate under 0.1% diluted hydrofluoric acid (dHF) less than 10 Å/min. As the nitrogen plasma used in the treatment may be directional, for example plasma treatment (nitrogen injection) in a direction from the top to the bottom of the trench, the treated silicon nitride film 204″ may have a nitrogen content gradient. As seen in the right part of FIG. 18, a nitrogen content gradient is shown, and the nitrogen content keeps decreasing as the depth increases, wherein the depth is measured from the topmost of the film 204″ into the film 204″ filled inside the trench TR′ (from top to bottom) and the nitrogen content increases from left to right. That is, the treated silicon nitride film 204″ becomes nitrogen-rich after the nitrogen plasma treatment, and the nitrogen content in the upper portion of the silicon nitride film 204″ is higher than the nitrogen content in the lower or bottom portion of the silicon nitride film 204″. In some embodiments, the film density of the silicon nitride film 204″ filled in the upper portion of the trench is also higher than the film density of the silicon nitride film 204″ filled in the lower or bottom portion of the trench. As higher film density leads to higher etching resistance, the etching resistance of the silicon nitride film 204″ filled in the upper portion of the trench is higher than the etching resistance of the silicon nitride film 204″ filled in the lower or bottom portion of the trench.

In accordance with an embodiment of the disclosure, a method for forming a semiconductor device structure is described. The method at least includes the following steps. A transistor layer is formed over a substrate and a trench is formed in the transistor layer. A depth to width ratio of the trench is greater than or equal to 3. The trench is then filled with a gap-fill material using a flowable chemical vapor deposition process, wherein a precursor and a reactant are used in the flowable chemical vapor deposition process, and a ratio of the precursor to the reactant is about 1.

In accordance with an embodiment of the disclosure, a method for forming a semiconductor device structure is described. The method at least includes the following steps. A transistor layer is formed over a substrate, wherein the transistor layer includes a plurality of nanostructures, source/drain structures aside the nanostructures, and gate structure around the nanostructures. A non-functional structure is then formed in the transistor layer, the formation of the non-functional structure at least includes the following steps. The transistor layer is patterned to form a trench for accommodating the non-functional structure, and a silicon nitride layer is formed to fill the trench using a bottom-up deposition process, wherein a wet etching rate of the silicon nitride layer to 0.1% diluted hydrofluoric acid is less than 10Å/min.

In accordance with yet another embodiment of the disclosure, a semiconductor device structure is described. The semiconductor device structure includes a plurality of nanostructure stacks, and each of the nanostructure stacks including nanostructures stacked over one another. The semiconductor device structure further includes source and drains between adjacent nanostructure stacks, a gate electrode layer surrounding the nanostructures, and a silicon nitride layer vertically extending through gate electrode layer. The silicon nitride layer has a nitrogen content gradient.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a transistor layer over a substrate;
forming a trench in the transistor layer, a depth to width ratio of the trench being greater than or equal to 3; and
filling the trench with a gap-fill material using a flowable chemical vapor deposition process, wherein a precursor and a reactant are used in the flowable chemical vapor deposition process, and a ratio of the precursor to the reactant is about 1.

2. The method of claim 1, wherein the flowable chemical vapor deposition process is performed at a temperature of about 0°° C. to about 200° C.

3. The method of claim 1, wherein the gap-fill material is liquid-like.

4. The method of claim 1, wherein the precursor is trisilylamine and the reactant includes ammonia and oxygen.

5. The method of claim 4, further comprising:
performing a curing process to the gap-fill material after the flowable chemical vapor deposition process with a UV light to form a cured gap-fill material, wherein the curing process is performed at a temperature of about 0° C. to about 200°° C.

6. The method of claim 5, further comprising:
performing a nitrogen plasma treatment to the cured gap-fill material after the curing process to form a silicon nitride layer in the trench.

7. The method of claim 6, wherein the nitrogen plasma treatment includes a microwave plasma process, an electron cyclotron resonance plasma process, a capacitively coupled plasma process, or an inductively coupled plasma process.

8. The method of claim 7, wherein the silicon nitride layer is seam-free and void-free.

9. The method of claim 7, wherein the silicon nitride layer has a nitrogen content gradient.

10. A method for forming a semiconductor device structure, comprising:
forming a transistor layer over a substrate, the transistor layer comprising a plurality of nanostructures, source/drain structures aside the nanostructures, and gate structure around the nanostructures; and
forming a non-functional structure in the transistor layer, wherein the forming of the non-functional structure comprises:
patterning the transistor layer to form a trench for accommodating the non-functional structure; and
forming a silicon nitride layer filling the trench using a bottom-up deposition process, wherein a wet etching rate of the silicon nitride layer to 0.1% diluted hydrofluoric acid is less than 10Å/min.

11. The method of claim 10, wherein an aspect ratio of the trench is no less than 3.

12. The method of claim 10, wherein the bottom-up deposition process comprises:
forming a flowable nitride-based material in the trench;
UV curing the flowable nitride-based material to form a solid-like film; and
plasma treating the solid-like film with a nitrogen plasma to form the silicon nitride layer.

13. The method of claim 12, wherein the flowable nitride-based material is formed using a flowable chemical vapor deposition process.

14. The method of claim 13, wherein the flowable chemical vapor deposition process is performed at a temperature of about 0°° C. to about 200° C.

15. The method of claim 12, wherein a ratio of a precursor and a reactant for forming the flowable nitride-based material is about 1.

16. The method of claim 12, wherein the flowable nitride-based material includes short chain polymers.

17. The method of claim 12, wherein the UV curing is performed at a temperature of about 0°° C. to about 200°° C.

18. A semiconductor device structure, comprising:
a plurality of nanostructure stacks, each of the nanostructure stacks including nanostructures stacked over one another;
source and drains between adjacent nanostructure stacks;
a gate electrode layer surrounding the nanostructures; and
a silicon nitride layer vertically extending through gate electrode layer, wherein the silicon nitride layer has a nitrogen content gradient.

19. The semiconductor device structure of claim 18, wherein the silicon nitride layer is free of vertical seam and void.

20. The semiconductor device structure of claim 18, wherein the silicon nitride layer includes tapered sidewalls.
